(19) United States
(12) Patent Application Publication
(10) Pub. No.: US 2021/0364912 A1
(43) Pub. Date: Nov. 25, 2021

(54) MASK TENSION FRAME AND MASK TENSION PROCESS

(71) Applicants: Ordos Yuansheng Optoelectronics Co., Ltd., Ordos (CN); BOE TECHNOLOGY GROUP CO., LTD., Beijing (CN)

(72) Inventors: Pu SUN, Beijing (CN); Shouhua LV, Beijing (CN); Zhen WANG, Beijing (CN)

(21) Appl. No.: 16/606,425

(22) PCT Filed: Apr. 30, 2019
(86) PCT No.: PCT/CN2019/085288

§ 371 Date: Oct. 18, 2019

(30) Foreign Application Priority Data
Jun. 20, 2018 (CN) 201810639566.7

(51) Int. Cl. G03F 1/64

(52) U.S. Cl. CPC G03F 1/64; B05C 21/005

(57) ABSTRACT

The present disclosure provides a mask tension frame and a mask tension process, where the mask tension frame includes a frame body and a supporting rib. The frame body is provided with a first surface, a second surface, and an opening. The first surface and the second surface are oppositely disposed, and the opening is recessed in the direction from the first surface toward the second surface. The supporting rib spans the opening of the frame body. A surface of the supporting rib for supporting the mask is higher than the first surface with respect to the second surface. When the mask is being tensed by the mask tension frame, at least a portion of the mask is supported by the supporting rib and at least a portion of the mask adjacent to an edge of the mask is supported by the first surface.

### CROSS-REFERENCE TO RELATED APPLICATIONS

The present application claims the priority to Chinese Patent Application No. 201810639566.7, filed on Jun. 20, 2018, which is incorporated herein by reference in its entirety.

### TECHNICAL FIELD

The present disclosure relates to the field of the OLED display technology and, in particular, relates to a mask tension frame and a mask tension process.

### BACKGROUND

OLED (Organic Light-Emitting Diode) display technology has gradually become the main direction of development of flat panel display technology due to its characteristics, such as thin and light devices, low power consumption, high contrast, high color gamut, and flexible display. OLED display technology mainly includes PMOLED (Passive Matrix OLED, Passive Matrix Organic Electroluminescent Diode) display technology and AMOLED (Active Matrix OLED, Active Matrix Organic Electroluminescent Diode) display technology.

The implementation of AMOLED display technology includes the “LTPS backplane+fine metal mask (FMM Mask)” method and the “Oxide backplane+WOLED+color film” method. The former method is mainly used for small-sized panels, such as display designs for mobile phones and mobile products, and the latter method is mainly used for large-sized panels such as screens and televisions.

In the “LTPS backplane+fine metal mask (FMM Mask)” method, a fine metal mask is required to be tensed. Achieving improvements in the flatness of the mask is an important technical problem to be solved.

### SUMMARY

According to an aspect of the present disclosure, a mask tension frame for tensing a mask is provided. The mask tension frame includes a frame body and a supporting rib, where the frame body is provided with a first surface, a second surface, and an opening, and the first surface and the second surface are oppositely disposed. The opening is recessed in a direction from the first surface toward the second surface. The supporting rib spans the opening of the frame body, and a surface of the supporting rib for supporting the mask is higher than the first surface with respect to the second surface. When the mask is being tensed by the mask tension frame, at least a portion of the mask is supported by the supporting rib, and at least a portion of the mask adjacent to an edge of the mask is supported by the first surface.

Specifically, the frame body is a frame structure provided with an opening; the supporting rib is fixed to the frame body, and the supporting rib spans the opening of the frame body. When the mask is being tensed by the mask tension frame, the mask edge is fixed on the frame body, the mask edge and the supporting rib are fixed to the same plane of the frame body, and a portion of the mask located at the opening is supported by the supporting rib.

In one embodiment of the present disclosure, the supporting rib is fixed to the first surface.

In one embodiment of the present disclosure, the number of the supporting ribs is plural.

In one embodiment of the present disclosure, a plurality of the supporting ribs are parallel to each other.

In one embodiment of the present disclosure, two of the plurality of supporting ribs are disposed adjacent to both sides of the opening.

In one embodiment of the present disclosure, two of the plurality of supporting ribs are symmetrically disposed on both sides of the opening.

In one embodiment of the present disclosure, an extending direction of the supporting rib is perpendicular to an extending direction of the mask.

In one embodiment of the present disclosure, the supporting rib is welded and fixed on the first surface of the frame body.

In one embodiment of the present disclosure, a surface of the supporting rib for supporting the mask is higher than the first surface by a distance of 15 μm to 50 μm.

In one embodiment of the present disclosure, the first surface is a plane.

In one embodiment of the present disclosure, a thickness of the supporting rib is in the range of 15 μm to 50 μm.

According to another aspect of the present disclosure, a mask tension process is provided, where the mask tension process includes:

providing a frame body, the frame body being provided with a first surface, a second surface, and an opening, where the first surface and the second surface are oppositely disposed and the opening is recessed in a direction from the first surface toward the second surface;

providing a supporting rib, making the supporting rib span the opening of the frame body, and making a surface of the supporting rib for supporting a mask higher than the first surface with respect to the second surface;

tensing the mask tightly on the first surface of the frame body using expansion equipment;

making at least a portion of the mask supported by the supporting rib, and making at least a portion of the mask adjacent to an edge of the mask supported by the first surface.

In one embodiment of the present disclosure, the making of the surface of the supporting rib for supporting a mask higher than the first surface with respect to the second surface comprises: making the supporting rib fixed to the first surface.

In one embodiment of the present disclosure, the providing of the supporting rib comprises: providing a plurality of the supporting ribs.

In one embodiment of the present disclosure, after providing the plurality of supporting ribs, the plurality of the supporting ribs are arranged parallel to each other.

In one embodiment of the present disclosure, after providing the plurality of supporting ribs, two of the plurality of supporting ribs are disposed adjacent to both sides of the opening.

In one embodiment of the present disclosure, two of the plurality of supporting ribs are arranged to be symmetrically disposed on both sides of the opening.

In one embodiment of the present disclosure, after the providing of the supporting rib, the mask tension process further comprises: making an extending direction of the supporting rib perpendicular to an extending direction of the mask.

In one embodiment of the present disclosure, after providing the supporting rib, the mask tension process further comprises: fixing the supporting rib on the first surface of the frame body by welding.

In one embodiment of the present disclosure, making at least a portion of the mask adjacent to an edge of the mask supported by the first surface comprises: welding the edge of the mask to the first surface of the frame body, and then a portion of the mask located at the opening is supported by the supporting rib.

### BRIEF DESCRIPTION OF THE DRAWINGS

The various objects, features, and advantages of the present disclosure will become more apparent by considering the following detailed description of the embodiments of the present disclosure in conjunction with the drawings. The drawings are only illustrative of the present disclosure and are not necessarily to scale. In the drawings, the same reference numerals always indicate the same or similar parts.

FIG. 1 is a top view of a mask tension frame of the related art;

FIG. 2 is a side cross-sectional view taken along line A-A of FIG. 1;

FIG. 3 is a schematic diagram of the flatness of the mask tensed on the mask tension frame of FIG. 1;

FIG. 4 is a top view of a mask tension frame according to an exemplary embodiment;

FIG. 5 is a side cross-sectional view taken along line B-B of FIG. 4; and

FIG. 6 is a schematic diagram of the flatness of the mask tensed on the mask tension frame of FIG. 4.

### DETAILED DESCRIPTION

Exemplary embodiments embodying the features and advantages of the present disclosure will be described in detail in the following description. It should be understood that the present disclosure is capable of various modifications in various embodiments and such modifications do not depart from the scope of the present disclosure. The description and drawings are to be regarded as illustrative rather than limiting.

In the following description of various exemplary embodiments of the present disclosure, reference is made to the accompanying drawings, and various exemplary structures, systems, and steps that can implement various aspects of the present disclosure are shown by way of example. It is understood that other specifics of the components, the structures, the exemplary devices, the systems, and the steps can be used, and structural and functional modifications can be made without departing from the scope of the disclosure. Moreover, although the terms “top”, “bottom”, “side”, “between”, and the like may be used in the specification to describe various exemplary features and elements of the present disclosure, these terms are used herein for convenience only, such as in the direction of the examples described in the drawings. Nothing in this specification should be construed as requiring a particular three-dimensional orientation of the structure to fall within the scope of the disclosure.

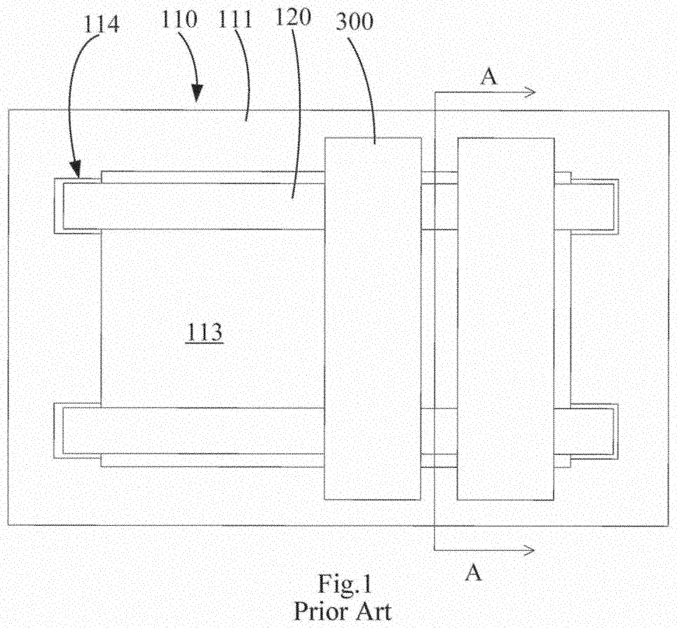

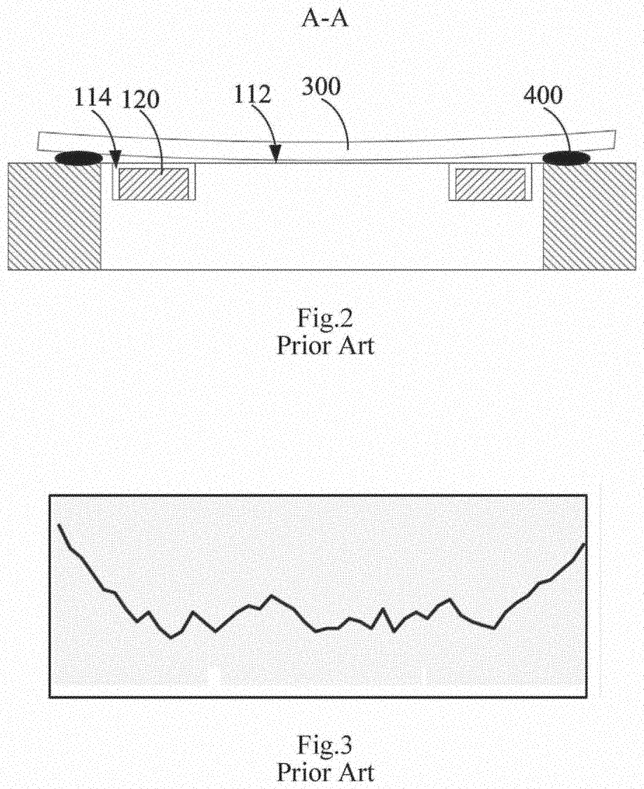

In related expansion process, as shown in FIG. 1 and FIG. 2, the mask 300 is welded to a top surface 112 of the frame 111 of the frame body 110, the supporting ribs 120 are welded to the bottom of the groove 114 formed in the frame 111, and the top surface of the supporting rib 120 for supporting the mask 300 is lower than the top surface 112. That is, the supporting rib 120 and the mask 300 are welded to different planes. Accordingly, the supporting effect of the supporting rib 120 on the portion of the mask 300 that is disposed above the opening 112 of the frame body 110 is less apparent. Moreover, as shown in FIG. 3, through experimental tests, it can be seen that after the mask 300 is soldered to the top surface 112 of the frame 111 using the above design solutions, such that the mask 300 exhibits a state in which both ends are lifted and the center is sunk, and the flatness difference between the two ends and the middle portion of the mask 300 is large.

Embodiment of the Mask Tension Frame

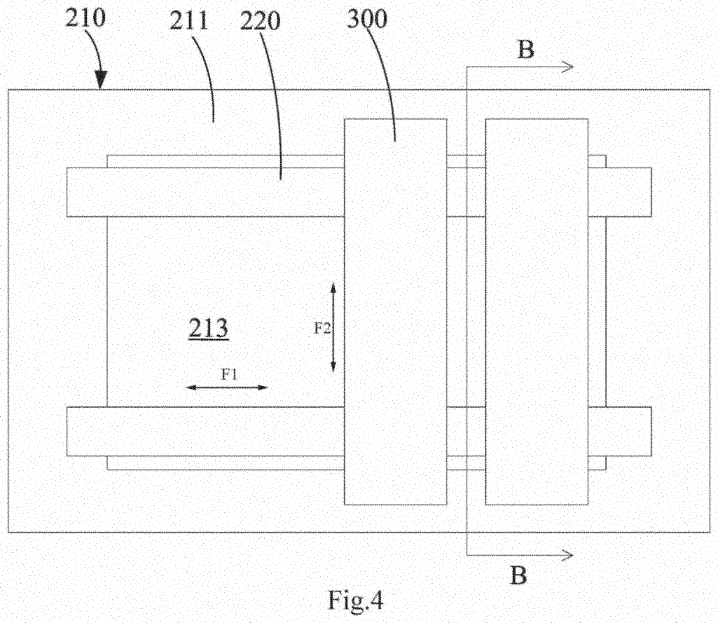

Referring to FIG. 4, a top view of a mask tension frame provided by the present disclosure is representatively shown. In the exemplary embodiment, the mask tension frame provided by the present disclosure is exemplified by a device for tensing the mask, further by a mask tension equipment of the “LTPS+FMM Mask” in AMOLED technology. It will be readily understood by those skilled in the art that in order to apply the related design of the present disclosure to other types of mask tension process, various modifications, additions, substitutions, deletions, or other changes may be made to the specific embodiments described below, which are still within the scope of principles of the mask tension frame of the present disclosure.

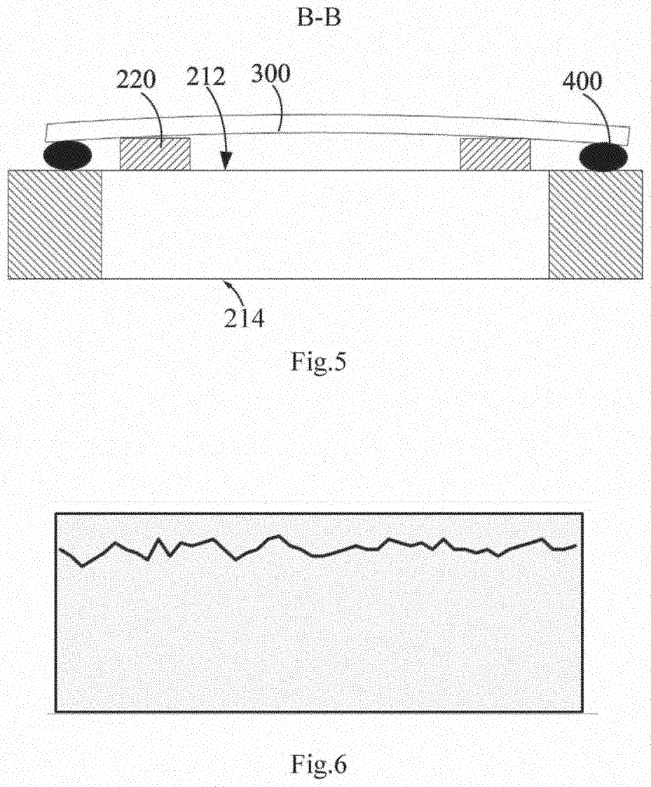

As shown in FIG. 4, in the embodiment, the mask tension frame provided by the present disclosure may be used to perform an expansion process for the mask 300, particularly for the fine metal mask 300 (FMM). In the embodiment, the mask tension frame mainly includes a frame body 210 and a supporting rib 220. Referring now to FIG. 5 and FIG. 6, a side cross-sectional view taken along line B-B of FIG. 4 is representatively shown in FIG. 5, a schematic diagram of the flatness of the mask tensed on the mask tension frame of FIG. 4 is representatively shown in FIG. 6, and FIG. 6 specifically shows the flatness test image of the portion of the mask that is above the opening of the expansion frame. The structure, connection manner, and functional relationship of the main components of the mask tension frame proposed by the present disclosure will be described in detail below with reference to the above drawings.

As shown in FIG. 4 and FIG. 5, in the embodiment, the frame body 210 is a frame structure provided with an opening 213, and the frame body 210 is provided with a first surface 212 and a second surface 214. It should be noted that, compared to the technical solution of the related art shown in FIG. 1, the “first surface 212” is an upper surface of the overall structure of the frame body 210, hereinafter referred to as a top surface 212, which is distinguished from the bottom surface of the groove 114 in FIG. 1. In the embodiment, the specific structure, shape, or size of the frame body 210 can refer to the design of the frame body 110 of the existed mask tension frame, the content shown in the drawings is merely an exemplary schematic state, and doesn't limit the structure, shape, or size of the frame body 210.

The supporting ribs 220 are fixed to the frame body 210, and the surface of the supporting rib 220 for supporting the mask 300 is higher than the top surface 212. As shown in FIG. 4 and FIG. 5, in the embodiment, the supporting rib 220 is directly fixed to the top surface 212 of the frame body 210, thereby the top surface of the supporting rib 220 is higher than the top surface 212 of the frame body 210. The supporting rib 220 spans the opening 213 of the frame body 210 and, in the embodiment, the number of the supporting ribs 220 is two. In the embodiment, the specific structure, shape, size, or number of the supporting ribs 220 can refer to the design of the supporting ribs 120 of the existed mask tension frame. The content shown in the drawings is merely an exemplary schematic state, and doesn't limit the structure, shape, size or number of the supporting ribs 220. Further, in the embodiment, the thickness of the supporting rib 220 may be in the range of 15 μm˜50 μm, and specifically may be 30 μm.

In accordance with the description above, as shown in FIG. 4 and FIG. 5, when the mask 300 is being tensed by the mask tension frame provided by the present disclosure, the edge of the mask 300 is fixed (for example welded) on the top surface 212 of the frame body 210, and a portion of the mask 300 located at the opening 213 is supported by the supporting ribs 220. Compared with the design, such as “the top surface of the supporting rib 120 is lower than the top surface 120 of the frame body 110, that is, the supporting rib 120 and the mask 300 are respectively fixed at different heights, that is, welded to different planes”, of the mask tension frame in related art, the top surface of the supporting rib 220 in the mask tension frame provided by the present disclosure is higher than the top surface 212 of the frame body 210. In one embodiment, the distance between the top surface of the supporting rib 220 and the first surface 212 is 15 μm to 50 μm, and may be 30 μm, and the mask 300 is stacked on the supporting ribs 220, and the edges of the mark 300 may also be supported on the top surface 212 of the frame body 210 at the same time. Therefore, the mask 300 can be simultaneously supported by the top surface 212 of the frame body 210 and the supporting ribs 220, that is, multilayer structures are sequentially overlapped. In the embodiment, the supporting rib 220 is directly fixed to the top surface 212 of the frame body 210, so that the mask 300 and the supporting ribs 220 may be fixed to a same surface of the frame body 210, that is, to the top surface 212. In the embodiment, the edges of the mask 300 can be fixed to the top surface 212 of the frame body 210 by laser welding.

Accordingly, refer to FIG. 6, which specifically shows a schematic diagram of the flatness state of the mask 300. In FIG. 6, the lateral direction of the flatness curve can be understood as the horizontal direction of the mask 300 (i.e. the expansion direction), and the longitudinal direction of the flatness curve can be understood as the state of flatness of the mask 300 at a certain position in the horizontal direction. Through tests and demonstration, it can be seen that, in the case of the design of the mask tension frame provided by the present disclosure is used, after the mask 300 is welded to the top surface 212 of the frame body 210, since the mask 300 and the supporting ribs 220 are welded to the same surface, that is, both are welded to the top surface 212 of the frame body 210, specifically, the two ends of the mask 300 are welded to the top surface 212 by the soldering structure 400, and the middle portion of the mask 300 is supported by the supporting ribs 220, tests have shown that the mask 300 has a state in which the difference in flatness between the both ends and the middle portion is small, that is, the mask 300 exhibits a better flatness state after being tensed. Furthermore, the present disclosure overcomes the prejudice perception inherent to those skilled in the art that “the overlapping of multilayer structures leads to a decrease in flatness” by the above-mentioned design and tests demonstration, that is, the present disclosure adopts a design in which “multilayer structures are sequentially overlapped”, that is, the frame body 210—the supporting ribs 220—the mask 300 are sequentially overlapped from bottom to top. Through tests demonstration, as shown in FIG. 6, based on the above described technical solution of welding on the same surface of the present disclosure, there is indeed a significant improvement in the flatness of the mask 300.

It should be noted that FIG. 4 and FIG. 5 only show the schematic state of the stacked relationship of each layer structure, and don't show the real structure of the mask 300 tensed and welded on the mask tension frame. In the embodiment, the portion of the mask 300 corresponding to the upper portion the frame 211 is welded to the top surface 212 of the frame body 210, the drawing exaggeratedly shows the state in which the soldering structure 400 is connected between the mask 300 and the frame body 210, and the true thickness of the supporting rib 220 and the mask 300 is on the order of micrometers, respectively. In the above-mentioned drawings, the size of the relevant structure in the thickness direction (vertical direction) is correspondingly exaggerated, so that the positional relationship of the laminated structure can be easily understood. In addition, when the mask 300 is welded to the first surface 212 of the frame 210, the edge portion of the mask 300 may be melted and integrated with the first surface 212. Therefore, FIG. 5 can only show the case of the soldering structure 400. Of course, 400 can also represent the melt at the edge of the mask 300.

Further, in the embodiment, the plurality of supporting ribs 220 may be arranged in parallel with each other.

Further, in the embodiment, the extending direction F1 of the supporting rib 220 may be perpendicular to an extending direction F2 of the mask 300.

Further, in the embodiment, the supporting ribs 220 are fixed to the top surface 212 of the frame body 210 by welding.

Referring to FIG. 5, in the embodiment, the top surface of the supporting rib 220 is a plane. Since the mask 300 is provided on the supporting ribs 220 and the edges of the mask 300 are fixed to the first surface 212 of the frame body 210, and the central portion of the mask 300 has a tendency to bend upward, as shown in FIG. 5, the profile of the mask 300 presents a slightly upward curved shape. In order to enable the top surface of the supporting rib 220 to fully support the lower surface of the mask 300, in the embodiment, the top surface of the supporting rib 220 is designed as an inclined surface, that is, the thickness of the support rib 220 is gradually increased from the edge portion of the mask 300 toward the central position of the mask 300, so as to make the top surface of the support rib 220 attach to the mask 300 as much as possible, thereby achieving better support.

It should be noted herein that the mask tension frame shown in the drawings and described in this specification is just a few examples of many types of the mask tension frames that can employ the principles of the present disclosure. It should be clearly understood that the principles of the present disclosure are in no way limited to any detail or any structure of the mask tension frame shown in the drawings or described in the specification.

Embodiment of the Mask Tension Process

In the exemplary embodiment, the mask tension process provided by the present disclosure is exemplified by a process for tensing the mask, further by a mask tension process of the “LTPS+FMM Mask” in AMOLED technology. It will be readily understood by those skilled in the art that in order to apply the related design of the present disclosure to other types of mask tension process, various modifications, additions, substitutions, deletions, or other changes may be made to the specific embodiments described below, which are still within the scope of principles of the mask tension process of the present disclosure.

In the embodiment, the mask tension process provided by the present disclosure mainly includes the followings steps:

providing a frame body 210, where the frame body 210 is provided with a first surface 212, a second surface 214, and an opening 213, the first surface 212 and the second surface 214 are oppositely disposed, and the opening 213 is recessed in a direction from the first surface 212 towards the second surface 214;

providing a supporting rib 220;

making a surface of the supporting rib 220 for supporting a mask higher than the first surface 212, and the supporting rib 220 spans the opening 213 of the frame body 210;

tensing the mask 300 tightly on the first surface 212 of the frame body 210 using expansion equipment;

making the mask simultaneously supported by the first surface 212 and the supporting rib 220, specifically, welding the mask edge to the first surface 212 of the frame body 210, and a portion of the mask 300 located at the opening 213 supported by the supporting rib 220.

In the embodiment, the making of the surface of the supporting rib 220 for supporting the mask 300 higher than the first surface 212 includes: making the supporting ribs 220 fixed to the first surface 212.

In the embodiment, the number of the supporting ribs 220 is plural.

In the embodiment, after providing a plurality of supporting ribs 220, arranging the plurality of supporting ribs 220 to be fixed to the first surface 212 of the frame body 210 in parallel with each other.

In the embodiment, after providing a plurality of the supporting ribs 220, two of the plurality of supporting ribs 220 are disposed adjacent to both sides of the opening 213.

In the embodiment, after providing a supporting rib 220, making the extending direction F1 of the supporting rib 220 perpendicular to the extending direction F2 of the mask 300.

In the embodiment, after providing a supporting rib 220, fixing the supporting rib 220 on the top surface 212 of the frame body 210 by welding.

In the embodiment, the steps of providing a frame body 210 and providing a supporting rib 220 of the above process can directly adopt the frame body 210 and the supporting rib 220 of the mask tension frame provided by the present disclosure.

It should be noted herein that the mask tension process shown in the drawings and described in this specification is just a few examples of many types of the mask tension process that can employ the principles of the present disclosure. It should be clearly understood that the principles of the present disclosure are in no way limited to any detail or any steps of the mask tension process shown in the drawings or described in the specification.

In summary, the technical solutions of the mask tension frame and the mask tension process proposed by the present disclosure realize “when the mask is tensed by the mask tension frame, the mask is supported by both the top surface of the frame body and the supporting ribs by adopting the design of “the top surface of the supporting rib is higher than the top surface of the frame body and the supporting rib is spanned the opening of the frame body”. Moreover, the present disclosure overcomes the prejudice perception inherent to those skilled in the art that “the overlapping of multilayer structures leads to a decrease in flatness”, that is, the present disclosure adopts a design in which “multilayer structures are sequentially overlapped”, through tests demonstration, the flatness of the mask is significantly improved. Accordingly, after the mask is tensed by the mask tension frame provided by the present disclosure, a sufficient support effect is provided by the support ribs and the mask is obtained a better flatness.

Exemplary embodiments of the mask tension frame and mask tension process proposed by the present disclosure are described above and/or illustrated in detail. The embodiments of the present disclosure are not limited to the specific embodiments described herein, but rather, the components and/or steps of each embodiment can be used independently and separately from the other components and/or steps described herein. Each component and/or each step of an embodiment may also be used in combination with other components and/or steps of other embodiments. In the description of elements/components/etc. described and/or shown in drawings herein, the terms “a”, “an”, and “the” are used to mean the presence of one or more elements/components/etc.

While the mask tension frame and mask tension process of the present disclosure have been described in terms of various specific embodiments, those skilled in the art will recognize that the implementation of the present disclosure can be modified within the spirit and scope of the claims.

1. A mask tension frame configured to tense a mask, comprising:
a frame body provided with a first surface, a second surface, and an opening, wherein the first surface and the second surface are oppositely disposed, and the opening is recessed in a direction from the first surface toward the second surface; and
a supporting rib spanning the opening of the frame body, wherein a surface of the supporting rib for supporting the mask is higher than the first surface with respect to the second surface, wherein, when the mask is being tensed by the mask tension frame, at least a portion of the mask is supported by the supporting rib and at least a portion of the mask adjacent to an edge of the mask is supported by the first surface.

2. The mask tension frame according to claim 1, wherein the supporting rib is fixed to the first surface.

3. The mask tension frame according to claim 2, wherein a number of the supporting ribs is plural.

4. The mask tension frame according to claim 3, wherein a plurality of the supporting ribs are parallel to each other.

5. The mask tension frame according to claim 3, wherein two of the plurality of supporting ribs are disposed adjacent to both sides of the opening.

6. The mask tension frame according to claim 2, wherein an extending direction of the supporting rib is perpendicular to an extending direction of the mask.

7. The mask tension frame according to claim 2, wherein the supporting rib is welded and fixed on the first surface of the frame body.

8. The mask tension frame according to claim 1, wherein the first surface is a plane.

9. A mask tension process, comprising:
providing a frame body, wherein the frame body is provided with a first surface, a second surface and an opening, the first surface and the second surface are oppositely disposed, and the opening is recessed in a direction from the first surface toward the second surface;
providing a supporting rib, making the supporting rib span the opening of the frame body, and making a surface of the supporting rib for supporting a mask is higher than the first surface with respect to the second surface,
tensing the mask tightly on the first surface of the frame body using expansion equipment;
making at least a portion of the mask supported by the supporting rib; and
making at least a portion of the mask adjacent to an edge of the mark supported by the first surface.

10. The mask tension process according to claim 9, wherein making the surface of the supporting rib for supporting the mask higher than the first surface with respect to the second surface comprises making the supporting rib fixed to the first surface.

11. The mask tension process according to claim 10, wherein providing the supporting rub comprises providing a plurality of supporting ribs.

12. The mask tension process according to claim 11, further comprising, after providing the plurality of supporting ribs, arranging the plurality of the supporting ribs parallel to each other.

13. The mask tension process according to claim 11, further comprising, after providing the plurality of supporting ribs, arranging two of the plurality of supporting ribs to be disposed adjacent to both sides of the opening.

14. The mask tension process according to claim 10, wherein after providing the supporting rib, the mask tension process further comprises:
making an extending direction of the supporting rib perpendicular to an extending direction of the mask.

15. The mask tension process according to claim 10, wherein after providing the supporting rib, the mask tension process further comprises:
fixing the supporting rib on the first surface of the frame body by welding.

16. The mask tension process according to claim 9, wherein making at least a portion of the mask supported by the supporting rib, and making at least a portion of the mask adjacent to an edge of the mask supported by the first surface comprises: welding the edge of the mask to the first surface of the frame body, and then a portion of the mask located at the opening is supported by the supporting rib.

17. The mask tension frame according to claim 3, wherein two of the plurality of supporting ribs are symmetrically disposed on both sides of the opening.

18. The mask tension frame according to claim 2, wherein a surface of the supporting rib for supporting the mask is higher than the first surface by a distance of 15 μm to 50 μm.

19. The mask tension frame according to claim 1, wherein a thickness of the supporting rib is in the range of 15 μm to 50 μm.

20. The mask tension process according to claim 16, further comprising arranging two of the plurality of the supporting ribs to be symmetrically disposed on both sides of the opening.
